(19) United States
(12) Patent Application Publication
(10) Pub. No.: US 2005/0064296 A1
(43) Pub. Date: Mar. 24, 2005

(54) Method for transmission increase at a position on a photo mask repaired with ionic radiation by means of thermal desorption

(75) Inventors: Ralf Ludwig, Munchen (DE); Michael Schopp, Ottobrunn (DE); Ulrich Wiedenmann, Eurasburg (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munich (DE)

(21) Appl. No.: 10/493,490

(22) PCT Filed: Oct. 18, 2002
(86) PCT No.: PCT/EP02/11688

(30) Foreign Application Priority Data
Oct. 24, 2001 (DE) 101 52 564.8
Nov. 28, 2001 (DE) 10158 339.7

(51) Int. Cl. G03C 5/00; G03F 9/00

(52) U.S. Cl. 430/5; 430/322; 430/323; 430/324

(57) ABSTRACT

The invention provides an improved method for repairing opaque defects on a photomask, in which an opaque chrome repair is carried out by means of an ion beam with gallium ions, and then the gallium ions are removed from the quartz blank by thermal desorption by means of an incineration process.

### CLAIM FOR PRIORITY

This application claims priority to International Application No. PCT/EP02/11688, which was filed in the German language on Oct. 18, 2002, which claims the benefit of priority to German Application Nos. 101 58 339.7 and 101 52 564.8, which were both filed in the German language on Oct. 24, 2001.

### TECHNICAL FIELD OF THE INVENTION

The present invention relates to a method for increasing transmission of a photomask which has been repaired using ion radiation, and to a correspondingly produced photomask.

### BACKGROUND OF THE INVENTION

What are known as mask blanks (photoblanks) are used as starting material for the production of photomasks for photolithographic processes. These mask blanks are polished quartz plates which are coated with a chrome layer and a layer of photoresist arranged above it. To avoid defects on the mask, the photomasks are fed to a device which checks for defects before being irradiated. This device optically checks whether the surface of the mask is contaminated by particle deposits or damaged in any other way. According to the prior art, dark defects which are detected on masks with a glass carrier, caused, for example, by undesired chrome residues, are vaporized by means of a precisely focused laser beam or repaired using an ion beam (e.g. gallium; FIB: focused ion beam). In a repair of this nature, gallium ions (Ga⁺) are implanted into the quartz glass of the blank, with the result that chrome residues on the glass carrier are sputtered away. However, these gallium ions lead to a considerable transmission loss at the repair location of the photomask. This applies in particular in the event of radiation of light with a wavelength λ of ≦248 nm during the photolithographic patterning of the semiconductor wafers. Therefore, according to the known prior art, the implanted gallium (gallium staining) is subsequently removed from the quartz glass in a cleaning step using a special “post-etching process”. In this step, an approx. 20 nm thick glass layer is removed from the quartz blank at the repair location in question by etching using xenon difluorides. However, in particular when alternating phase-shift masks are being used, this disadvantageously has the effect of shifting the phase angle.

### SUMMARY OF THE INVENTION

In one embodiment of the invention, there is a method for repairing opaque defects on a photomask, in which an opaque chrome repair is carried out by means of an ion beam preferably with gallium ions, and then the ions are removed from the quartz blank by thermal desorption by means of an incineration process.

In one aspect of the invention, a second incineration process for post-repair is carried out after a first incineration process.

In another aspect of the invention, the incineration is carried out at approximately 150° C.

In still another aspect of the invention, the incineration is carried out in an H/O plasma.

In another embodiment, there is a photomask, where the photomask has been repaired using the method described above.

### DETAILED DESCRIPTION OF THE INVENTION

The present invention provides an improved repair method which avoids the above drawbacks.

According to one embodiment of the invention, after an opaque chrome repair is carried out by means of the ion beam, the mask is placed into an incinerator (H/O plasma). As a result, the ions which are present in the quartz glass, e.g. gallium ions, are removed from the quartz blank through thermal desorption.

One advantage of the method according to the invention is that the quartz is not damaged, since the elimination of the removal of material from the quartz glass at the repair location means that it is impossible for any phase shifts to occur in alternating phase-shift masks, and since no edges are produced, which would cause intensity losses at the edges of the cleaning step resulting from diffraction of the light at an edge. Moreover, a repair which has become physically too small or insufficient removal of the chrome can be post-repaired in a subsequent second step. This was fundamentally no longer possible with a cleaning step carried out in the interim in accordance with the prior art, on account of the resulting steps in the quartz glass.

According to one exemplary embodiment, a quartz blank which is known per se substantially comprises a polished quartz glass plate. This quartz glass plate is usually coated with a thin chrome layer or MoSiON layer with a thickness of approximately 100 nm. According to the repair method of the invention, there is no preliminary treatment of the photoblank. Dark defects in the photomask are repaired by means of an ion beam (focused ion beam). The gallium ions which are implanted in the process are then expelled from the quartz glass in a subsequent incineration step in accordance with the invention. The incineration process takes place in an H/O plasma (1:1) at a temperature of approximately 150° C. The duration of the incineration process is approximately 15 min; in the process, the thermal desorption or expulsion of the gallium ions takes place. A known standard final cleaning method is used for the subsequent treatment, removing any particles which are present from the quartz blank.

According to tests which have been carried out, the difference in intensity prior to the incineration step between the “defective” repair location and an “intact” reference location is, for example, approximately 10%. The incineration reduces this difference in intensity to approximately 1% without damaging the quartz glass.

1. A method for repairing opaque defects on a photomask, comprising:
performing an opaque chrome repair by means of an ion beam with gallium ions; and
removing the ions from the quartz blank by thermal desorption by means of an incineration process.

2. The method as claimed in claim 1, wherein a second incineration process for post-repair is carried out after a first incineration process.

3. The method as claimed in claim 2, wherein the incineration is performed at approximately 150° C.

4. The method as claimed in claim 3, wherein the incineration is performed in an H/O plasma.

5. A photomask, the photomask being repaired according to the following:
performing an opaque chrome repair by means of an ion beam with gallium ions; and
removing the ions from the quartz blank by thermal desorption by means of an incineration process.
